(19) United States
(12) Patent Application Publication
(10) Pub. No.: US 2016/0124844 A1
(43) Pub. Date: May 5, 2016

(54) DATA STORAGE DEVICE AND FLASH MEMORY CONTROL METHOD

(71) Applicant: Silicon Motion, Inc., Jhubei City (TW)

(72) Inventor: Yi-Kang CHANG, New Taipei City (TW)

(73) Assignee: Silicon Motion, Inc.

(21) Appl. No.: 14/802,611

(22) Filed: Jul. 17, 2015

(30) Foreign Application Priority Data
Oct. 31, 2014 (TW) 103137752

(51) Int. Cl. G06F 12/02; G11C 14/00

(52) U.S. Cl. CPC G06F 12/0246; G11C 14/0063; G06F 12/0253; G06F 2212/7201; G06F 2212/7205

(57) ABSTRACT

A flash memory control technology with high performance efficiency. A logical block table is managed on a random access memory to record logical blocks of breakpoints of sequential write operations issued from a host to write a flash memory. It is prohibited from performing garbage collection on the logical blocks recorded in the logical block table. In this manner, the system resources are no longer wasted by hastily organizing incomplete sequential write data.

### CROSS REFERENCE TO RELATED APPLICATIONS

This Application claims priority of Taiwan Patent Application No. 103137752, filed on Oct. 31, 2014, the entirety of which is incorporated by reference herein.

### BACKGROUND OF THE INVENTION

1. Field of the Invention

The present invention relates to data storage devices with flash memory and flash memory control methods.

2. Description of the Related Art

Flash memory, a data storage medium, is common in today's data storage devices. A NAND flash is one common type of flash memory.

For example, flash memory is typically used in memory cards, USB flash devices, solid-state drives, and so on. In another application with multi-chip package technology, a NAND flash chip and a controller chip are combined in one package as an embedded multi-media card (e.g. eMMC).

The storage space of a flash memory generally provides a plurality of physical blocks, and each physical block includes a plurality of physical pages. To release the storage space for reuse, an erase operation has to be performed on a block-by-block basis, to release space one block at a time. When updating data, the new data is written into a spare space rather than being overwritten on old data and the old data has to be invalidated. Thus, the storage space management of flash memory is more complex than other storage mediums. A controller design especially for flash memory is therefore called for.

### BRIEF SUMMARY OF THE INVENTION

A flash memory control technology with high efficiency is shown.

A data storage device in accordance with an exemplary embodiment of the disclosure comprises a flash memory and a control unit. The flash memory provides a storage space that is divided into a plurality of physical blocks with each physical block comprising a plurality of physical pages. The control unit comprises a microcontroller and a random access memory and is coupled between a host and the flash memory. The microcontroller is configured to manage a logical block table in the random access memory to record logical blocks of breakpoints of sequential write operations issued from the host to write the flash memory. The microcontroller is configured to prohibit garbage collection on the logical blocks recorded in the logical block table.

A flash memory control method in accordance with an exemplary embodiment of the disclosure comprises the following steps: managing a logical block table in a random access memory to record logical blocks of breakpoints of sequential write operations issued from a host to write a flash memory; and prohibiting garbage collection on the logical blocks recorded in the logical block table.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 depicts a storage space provided by a flash memory 100;

FIG. 2A depicts how a flash memory stores data in a page mode;

FIG. 2B depicts how a flash memory stores data in a block mode;

FIG. 3A and FIG. 3B depict a data storage device 300 in accordance with an exemplary embodiment of the disclosure, which stores data in a hybrid mode and controls and manages the valid data collection of sequential write data; and

FIG. 4 is a flowchart depicting the management of a logical block table SWTAB in accordance with an exemplary embodiment of the disclosure.

### DETAILED DESCRIPTION OF THE INVENTION

The following description shows exemplary embodiments carrying out the invention. This description is made for the purpose of illustrating the general principles of the invention and should not be taken in a limiting sense. The scope of the invention is best determined by reference to the appended claims.

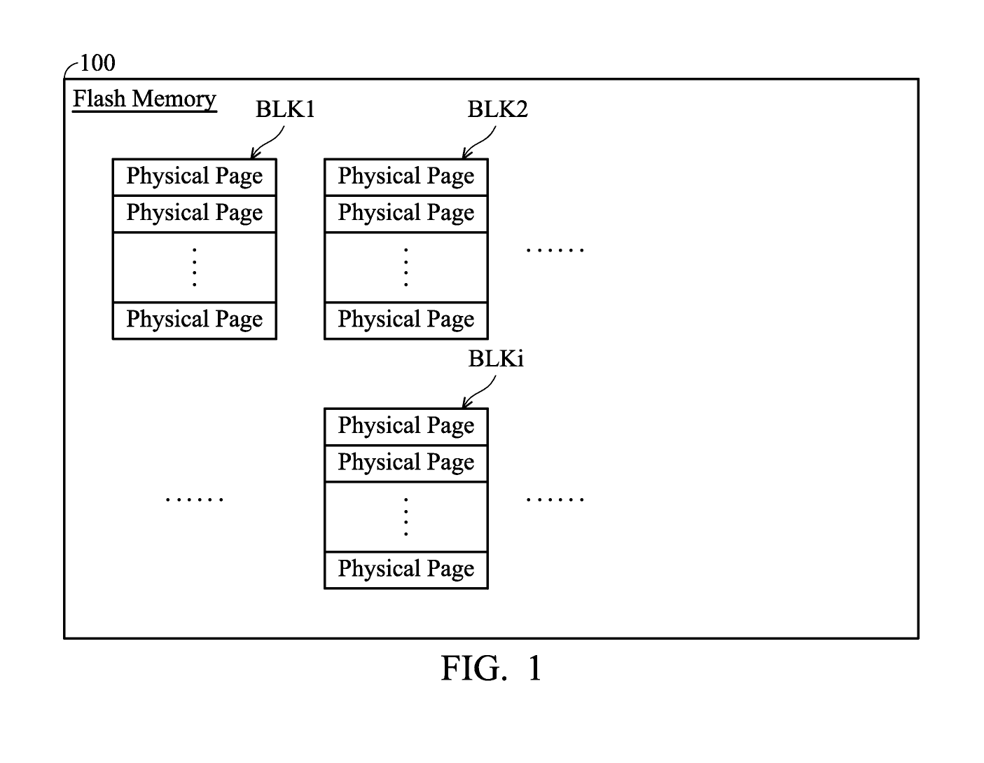

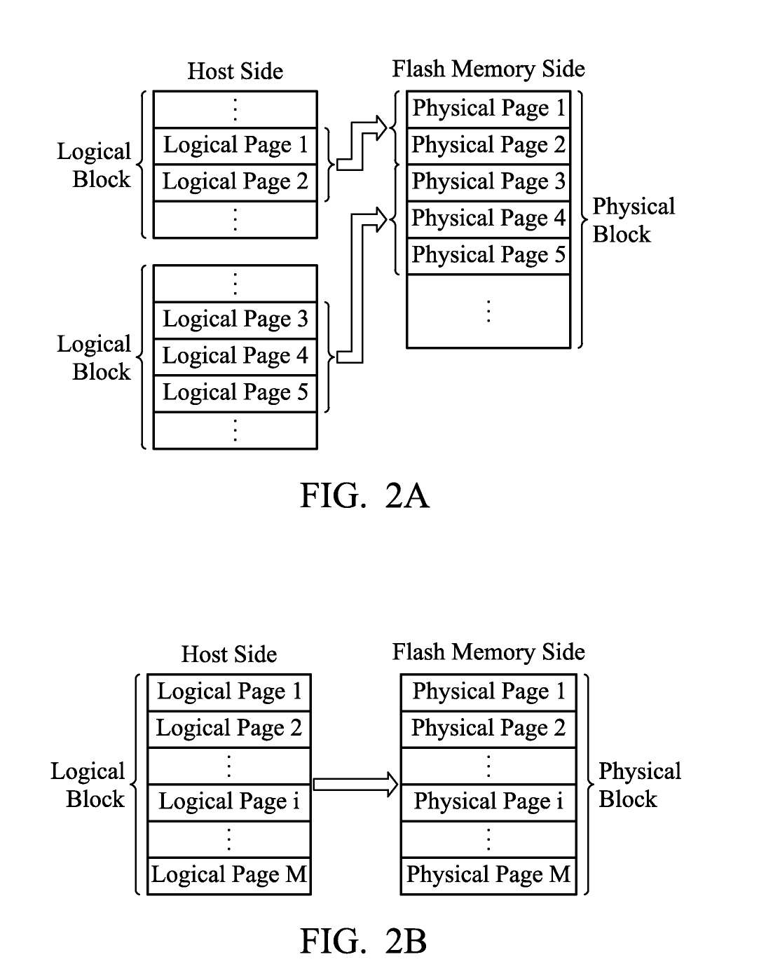

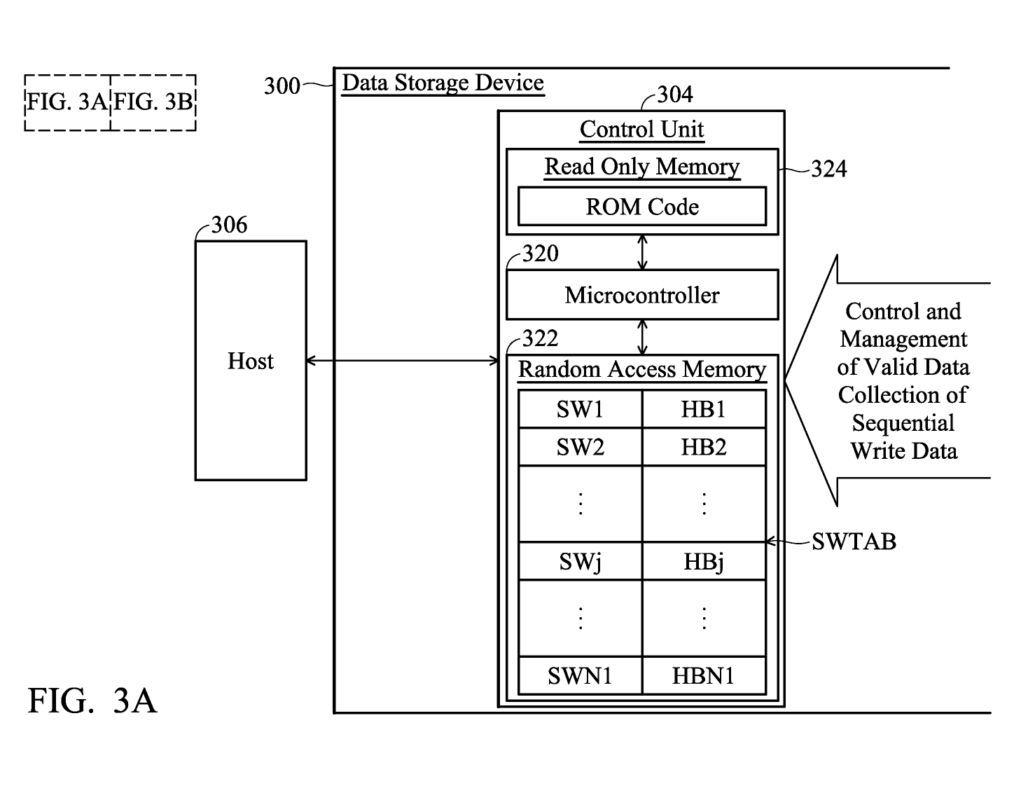

FIG. 1 depicts a storage space provided by a flash memory 100, which is divided into a plurality of physical blocks BLK1, BLK2 . . . BLKi . . . Each physical block comprises a plurality of physical pages. The host side issuing write commands in logical addresses dynamically uses the storage space of a flash memory. Thus, a dynamical logical-to-physical address mapping relationship is established. FIG. 2A illustrates a logical-to-physical address mapping relationship to show how a flash memory stores data in a page mode. FIG. 2B illustrates a logical-to-physical address mapping relationship to show how a flash memory stores data in a block mode.

Referring to FIG. 2A, when being operated in a page mode, one single physical block of the flash memory may be allocated to store data of multiple logical blocks at the host side. As shown, the physical pages 1 and 2 are allocated to store data for logical pages 1 and 2, and the physical pages 3 to 5 are allocated to store data for logical pages 3 to 5. The logical pages 1 and 2 belong to one logical block and the logical pages 3 to 5 belong to another logical block. Such a page mode operation allows for flexible use of each physical block.

Referring to FIG. 2B, when being operated in a block mode, one single logical block at the host side corresponds to one single physical block of the flash memory. As shown, the logical pages 1, 2 . . . i . . . M of one single logical block correspond to the physical pages 1, 2 . . . i . . . M of one single physical page in sequence. The block mode operation results in a quite low data quantity of the logical-to-physical mapping information between a host and a flash memory because the mapping information is just at a block level. In contrast, according to the page mode operation shown in FIG. 2A, logical-to-physical mapping information showing the logical pages corresponding to the different physical pages in detail is required.

Combining the advantages of the page mode operation and the block mode operation, in the disclosure, the flash memory stores data in a hybrid mode, by which a run-time write block is managed to store data in the page mode, and data blocks (in a data pool) are put in order to store data in the block mode.

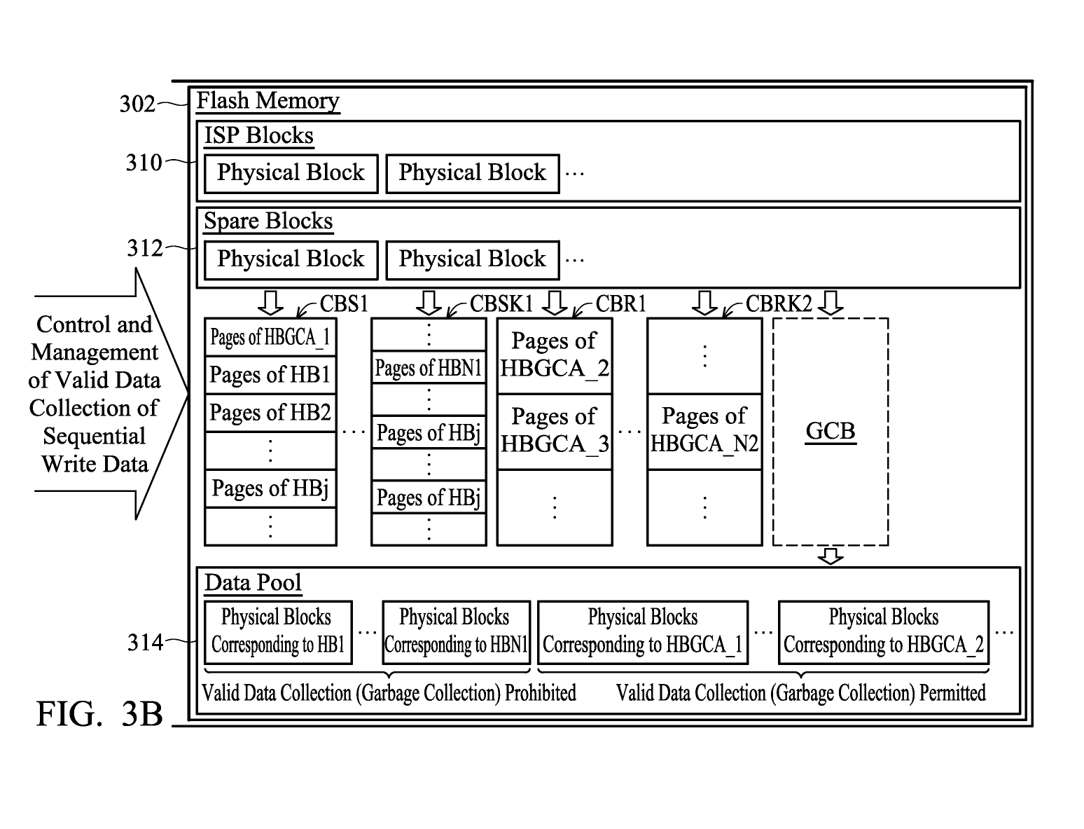

FIG. 3A and FIG. 3B depict a data storage device 300 in accordance with an exemplary embodiment of the disclosure, which comprises a flash memory 302 and a control unit 304. The control unit 304 is coupled between a host 306 and the flash memory 302 to operate the flash memory 302 in accordance with the commands issued from the host 306.

The storage space of the flash memory 302 is allocated to provide ISP (in-system-program) blocks 310, spare blocks 312, run-time write blocks CBS1 . . . CBSK1 and CBR1 . . . CBRK2, and a data pool 314. The ISP blocks 310 store in-system programs (ISPs). The run-time write blocks CBS1 . . . CBSK1 and CBR1 . . . CBRK are allocated from the spare blocks 312 and are written with the data issued from the host 306 in the page mode. The data written in the run-time write blocks CBS1 . . . CBSK1 and CBR1 . . . CBRK in the page mode then is pushed into the data pool 314 as data blocks in the block mode. In an exemplary embodiment, a garbage collection operation (for valid data collection) is introduced to collect the data of the same logical block into the same physical block and then pushes the physical block containing data of the same logical block into the data pool 314 as a data block. According to the garbage collection operation, a valid data collection block GCB (newly allocated and illustrated in dashed lines) is provided from the space blocks 312 for valid data collection, and is pushed into the data pool 314 after the valid data collection.

The control unit 304 includes a microcontroller 320, a random access memory 322 (e.g. an SRAM) and a read only memory 324. The read only memory 324 stores read only codes (e.g. ROM code). The microcontroller 320 operates by executing the ROM code stored in the read-only memory 324 or/and by executing the ISPs stored in the ISP blocks 310 of the flash memory 302.

As shown, the microcontroller 320 is configured to manage a logical block table SWTAB in the random access memory 322 to use the logical block table SWTAB to record logical blocks of breakpoints of sequential write operations issued from the host 306 to write the flash memory 302 and thereby to control and manage the valid data collection of sequential write data.

As shown, the logical block table SWTAB records logical blocks HB1, HB2 . . . HBj . . . HBN1 of breakpoints of N1 sequential write operations SW1, SW2 . . . SWj . . . SWN1, and the data pool 314 contain physical blocks which were previously collected in the data pool 314 corresponding to the logical blocks HB1, HB2 . . . HBj . . . HBN1. The microcontroller 320, however, is configured to prohibit the valid data collection of the logical blocks HB1, HB2 . . . HBj . . . HBN1 recorded in the logical block table SWTAB. However, as for the logical blocks HBGCA_1, HBGCA_2, HBGCA_3 . . . HBGCA_N2 not recorded in the logical block table SWTAB, the garbage collection is allowed. One of the logical blocks HBGCA_1, HBGCA_2, HBGCA_3 . . . HBGCA_N2 not recorded in the logical block table SWTAB may be chosen to be a selected logical block. The data of the selected logical block may be spread over the run-time write blocks CBS1 . . . CBSK1 and CBR1 . . . CBRK2 or even a physical block (corresponding to the selected logical block) in the data pool 314. Those data will be collected into the newly allocated valid data collection block GCB and then be pushed into the data pool 314 to replace the physical block that was previously corresponding to the selected logical block, but now has only invalid data remaining. As for the logical blocks HB1, HB2 . . . HBj . . . HBN1 those are prohibited from garbage collection, the corresponding data is accumulated in the run-time write blocks CBS1 . . . CBSK1 and CBR1 . . . CBRK2 and, when the prohibition is repealed, the run-time write blocks corresponding thereto are released at once. In this manner, the operating efficiency of the flash memory 302 is considerably improved in comparison with conventional techniques.

The microcontroller 320 is further configured to choose the selected logical block based on a valid page count per physical block. For example, between the run-time write blocks with all logical blocks permitted for garbage collection, the logical blocks corresponding to the run-time write block with the highest valid page count are all regarded as the selected logical blocks with the garbage collection performed thereon one by one to release the space of the run-time write block for reuse and, accordingly, the physical blocks corresponding thereto in the data pool 314 are replaced.

In the exemplary embodiment of FIG. 3A and FIG. 3B, sequential data is written into the flash memory 302 separately from random data. As shown, run-time write blocks CBS1 . . . CBSK1 are allocated for reception of sequential data and run-time write blocks CBR1 . . . CBRK2 are allocated for reception of random data.

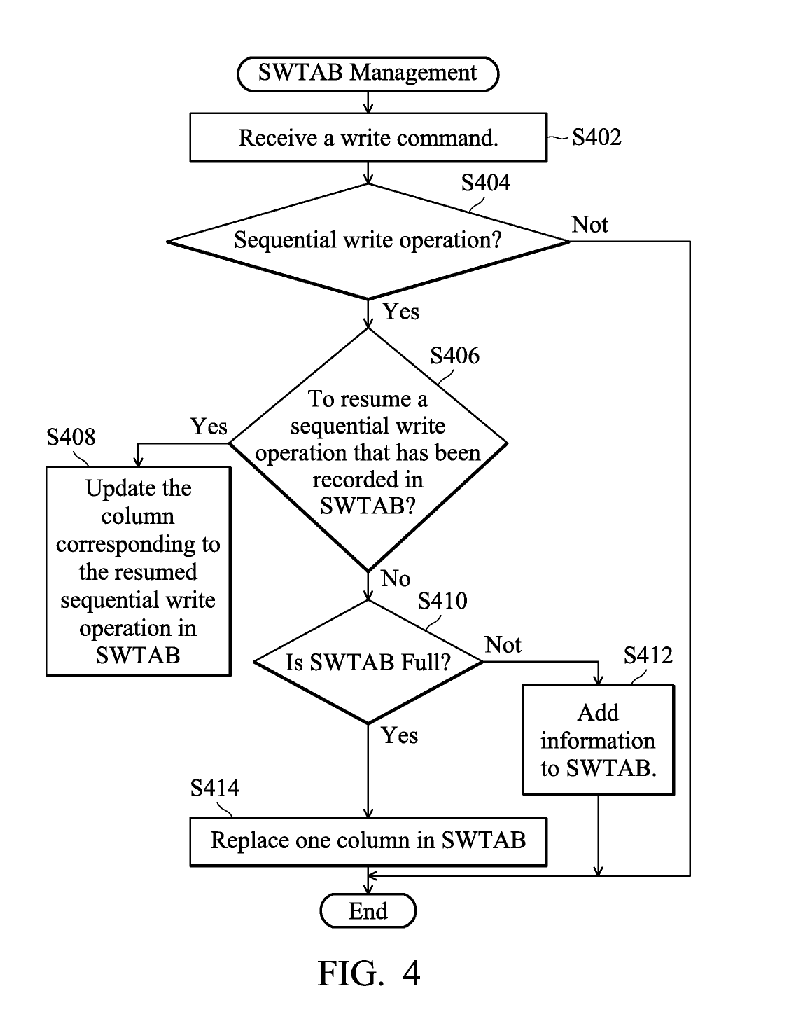

FIG. 4 is a flowchart depicting the management of the logical block table SWTAB. In step S402, a write command issued from the host 306 is received. In step S404, it is determined whether the write command is a sequential write operation, e.g. writing data along continuous logical addresses. In a multithread architecture, a sequential write operation may be interrupted by the suspension of a thread and thereby divided into slices and separately executed. In step S404, the write commands for the divided slices of sequential data writing may be further recognized. When it is determined in step S404 that the write command received in step S402 is irrelevant to a sequential write operation, no change is made to the logical block table SWTAB and the procedure ends.

When it is determined in step S404 that the write command received in step S402 is about a sequential write operation, step S406 is performed to determine whether the write command is about a resumed sequential write operation that resumes a sequential write operation recorded in the logical block table SWTAB. When it is determined in step S406 that the write command received in step S402 is about resuming a sequential write operation, step S408 is performed to update the information about the resumed sequential write operation in the logical block table SWTAB. In this manner, the logical block previously recorded in the logical block table SWTAB is released for garbage collection and thereby the valid data about the logical block released from the logical block table SWTAB is collected and put in order into the data pool 314.

When it is determined in step S402 that the write command received in step S402 is not to resume an interrupted sequential write operation but is another new sequential write operation, step S410 is performed to determine whether the logical block table SWTAB has any spare space to record the breakpoint of the new sequential write operation. When it is determined in step S410 that the logical block table SWTAB still has a blank column, step S412 is performed to record the logical address of the breakpoint of the new sequential write operation into the blank column of the logical block table SWTAB. When it is determined in step S410 that the logical block table SWTAB is full, step S414 is performed to replace one logical block recorded in the logical block table SWTAB by the logical block of the breakpoint of the new sequential write operation. In an exemplary embodiment, the column that has not changed longer than other columns in the logical block table is selected to be replaced.

The invention further involves flash memory control methods, which are not limited to any specific controller architecture. Furthermore, any technique using the aforementioned concept to control a flash memory is within the scope of the invention.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A data storage device, comprising:
a flash memory, providing a storage space divided into a plurality of physical blocks with each physical block further divided into a plurality of physical pages;
a control unit, comprising a microcontroller and a random access memory and coupled between a host and the flash memory,
wherein:
the microcontroller is configured to manage a logical block table in the random access memory to record logical blocks of breakpoints of sequential write operations issued from the host to write the flash memory; and
the microcontroller is configured to prohibit garbage collection on the logical blocks recorded in the logical block table.

2. The data storage device as claimed in claim 1, wherein:
the microcontroller is configured to allocate the flash memory to provide at least one run-time write block from the physical blocks for reception of data issued from the host;
the microcontroller is configured to record mapping information about the run-time write block that indicates logical pages corresponding to the physical pages of the run-time write block in detail; and
the microcontroller is configured to perform the garbage collection by collecting valid data of one logical block into one physical block that is to be pushed into a data pool.

3. The data storage device as claimed in claim 2, wherein:
the microcontroller is configured to perform the garbage collection to allocate the flash memory to provide a valid data collection block from the physical blocks, use the valid data collection block to collect valid data spread over the run-time write block and the data pool corresponding to a selected logical block, and push the valid data collection block into the data pool; and
the selected logical block is not recorded in the logical block table.

4. The data storage device as claimed in claim 3, wherein:
the microcontroller is configured to choose the selected logical block in accordance with a valid page count per physical block.

5. The data storage device as claimed in claim 4, wherein:
the microcontroller is configured to update the logical block table in accordance with a resumed sequential write operation.

6. The data storage device as claimed in claim 5, wherein:
the microcontroller is configured to use a blank column of the logical block table to record a logical block of a breakpoint of a new sequential write operation that has not been recorded in the logical block table.

7. The data storage device as claimed in claim 6, wherein:
when the logical block table is full, the microcontroller is configured to update a column that has not changed longer than other columns in the logical block table to record the logical block of the breakpoint of the new sequential write operation.

8. A flash memory control method, comprising:
managing a logical block table in a random access memory to record logical blocks of breakpoints of sequential write operations issued from a host to write a flash memory; and
prohibiting garbage collection on the logical blocks recorded in the logical block table.

9. The flash memory control method as claimed in claim 8, further comprising:
allocating the flash memory to provide at least one run-time write block from a plurality of physical blocks of the flash memory for reception of data issued from the host, each physical block comprising a plurality of physical pages;
recording mapping information about the run-time write block that indicates logical pages corresponding to the physical pages of the run-time write block in detail; and
performing the garbage collection by collecting valid data of one logical block into one physical block that is to be pushed into a data pool.

10. The flash memory control method as claimed in claim 9, further comprising:
performing the garbage collection to allocate the flash memory to provide a valid data collection block from the physical blocks; and
using the valid data collection block to collect valid data spread over the run-time write block and the data pool corresponding to a selected logical block and pushing the valid data collection block into the data pool,
wherein the selected logical block is not recorded in the logical block table.

11. The flash memory control method as claimed in claim 10, further comprising:
choosing the selected logical block in accordance with a valid page count per physical block.

12. The flash memory control method as claimed in claim 11, further comprising:
updating the logical block table in accordance with a resumed sequential write operation.

13. The flash memory control method as claimed in claim 12, further comprising:
using a blank column of the logical block table to record a logical block of a breakpoint of a new sequential write operation that has not been recorded in the logical block table.

14. The flash memory control method as claimed in claim 13, further comprising:
when the logical block table is full, updating a column that has not changed longer than other columns in the logical block table to record the logical block of the breakpoint of the new sequential write operation.
